(19) United States
(12) Patent Application Publication
(10) Pub. No.: US 2021/0173980 A1
(43) Pub. Date: Jun. 10, 2021

(54) METHOD OF MODELLING A SEDIMENTARY BASIN USING A HEX-DOMINANT MESH REPRESENTATION

(71) Applicant: IFP Energies nouvelles, Rueil-Malmaison Cedex (FR)

(72) Inventor: Daniele COLOMBO, RUEIL-MALMAISON CEDEX (FR)

(21) Appl. No.: 17/247,229

(22) Filed: Dec. 4, 2020

(30) Foreign Application Priority Data
Dec. 5, 2019 (FR) 19/13.783

(51) Int. Cl. G06F 30/23; G01V 99/00; G01V 1/52

(52) U.S. Cl. CPC G06F 30/23; G01V 1/52; G01V 99/005

(57) ABSTRACT

The present invention relates to a method of modelling a sedimentary basin by means of a numerical basin simulation solving at least a balance equation of poromechanics according to a face-based smoothed finite-element method for determining at least a stress field and a deformation field. The method according to the invention notably comprises the following steps: subdividing the hexahedral cells of a mesh representation of a state of the basin into at least eight hexahedral subcells, determining a transition relation between the degrees of freedom of the nodes of the subcells and the degrees of freedom of the nodes of the cell to which the subcells belong, and determining a stiffness and nodal forces from at least this transition relation and a strain-displacement relation determined for the subcells.

### FIELD OF THE INVENTION

The present invention relates to the field of petroleum reservoir or geological gas storage site exploration and exploitation.

Petroleum exploration is the search for hydrocarbon reservoirs within a sedimentary basin. Understanding the principles of hydrocarbon genesis and the connections thereof with the subsurface geological history has allowed to develop methods for assessing the petroleum potential of a sedimentary basin.

The general procedure for assessing the petroleum potential of a sedimentary basin comprises shuttles between:
a prediction of the petroleum potential of the sedimentary basin, from available data relative to the basin studied (outcrops, seismic surveys, drilling data for example). This prediction aims to better understand the architecture and the geological history of the basin studied, and notably to study whether hydrocarbon maturation and migration processes may have developed, to identify subsurface zones where these hydrocarbons may have accumulated, to define which zones have the best economic potential, assessed from the volume and the nature of the hydrocarbons probably trapped (viscosity, rate of mixing with water, chemical composition, etc.), as well as their operating cost (controlled for example by the fluid pressure and depth),
exploratory drilling operations in the various zones having the best potential, in order to confirm or invalidate the previously predicted potential and to acquire new data intended to fuel new and more precise studies.

Petroleum exploitation of a reservoir consists, from the data collected during the petroleum exploration phase, in selecting the reservoir zones with the best petroleum potential, in defining optimum exploitation schemes for these zones (using reservoir simulation for example in order to define the numbers and positions of the exploitation wells allowing optimum hydrocarbon recovery), in drilling exploitation wells and, in general terms, in setting up the production infrastructures necessary for reservoir development.

A sedimentary basin results from the deposition, over geological times, of sediments within a depression of the Earth's crust. These soft and water-rich sediments are then subjected, as they are progressively buried in the basin, to pressure and temperature conditions that convert them to compact sedimentary rocks referred to as geological layers.

The current architecture of a sedimentary basin notably results from a mechanical deformation of the subsoil over geological times. This deformation comprises, a minima, a compaction of the geological layers due to the gradual burial of these layers in the basin, under the effect of the supply of new sediments. However, a sedimentary basin is also most often subjected to large-scale tectonic movements, generating for example geological layer folding, or faults causing breaks in the geological layers.

The nature of the hydrocarbons present in a sedimentary basin notably depends on the type of organic matter present in the deposited sediments, and on the pressure and temperature conditions undergone by the basin over geological times.

FIG. 1 schematically shows a sedimentary basin comprising several geological layers (a, c) delimited by sedimentary interfaces (b) traversed by a fault (e), and a hydrocarbon accumulation (d) in one of the geological layers of the basin considered (c).

Formation of a sedimentary basin thus involves a large number of complex physical and chemical processes, which may additionally interact with one another. Given such complexity, prediction of the petroleum potential of a sedimentary basin requires computer tools allowing to simulate, as realistically as possible, the physical and chemical phenomena involved in the formation of the basin studied.

This type of reconstruction of the formation history of a sedimentary basin, also referred to as “basin modelling”, is most often performed by means of a family of computer tools allowing to simulate in one, two or three dimensions, the sedimentary, tectonic, thermal, hydrodynamic, organic and inorganic chemical processes involved in the formation of a petroleum basin.

Basin modelling conventionally comprises three steps:
a step of constructing a mesh representation of the basin studied, known as geomodelling. This mesh representation (also referred to as mesh) is most often structured in layers, i.e. a group of cells is assigned to each geological layer of the modelled basin. Then, each cell of this mesh is filled with one or more petrophysical properties, such as porosity, facies (clay, sand, etc.) or the organic matter content at the time of sedimentation. The construction of this model is based on data acquired through seismic surveys, measurements in wells, core drilling, etc.;
a step of structural reconstruction of this mesh, representing prior states of the basin architecture. This step can be carried out using a method referred to as “backstripping”, or a method referred to as structural restoration;
a step of numerical simulation of physical phenomena taking place during the basin evolution and contributing to the formation of oil traps. This step, known as “basin simulation”, is based on a discretized representation of space and time for reconstructing the basin formation over geological times. In particular, basin simulation allows to simulate, over geological times, the formation of hydrocarbons from notably the organic matter initially buried with the sediments, the state of the stresses and strains in the basin, and the transport of these hydrocarbons, from the rocks in which they are formed to those where they are trapped. Basin simulation thus provides a map of the subsoil at the current time, showing the probable location of the reservoirs, as well as the proportion, the nature and the pressure of the hydrocarbons trapped therein. An example of such a basin simulator is the TemisFlow® software (IFP Energies nouvelles, France).

Thus, this integrated procedure allowing the phenomena that have caused hydrocarbon generation, migration and accumulation in sedimentary basins to be taken into account and analysed allows the success rate to be increased when drilling an exploration well, thus enabling better exploitation of this basin.

### BACKGROUND OF THE INVENTION

The following documents are mentioned in the description:
Cook, Robert D., Finite Element Modeling for Stress Analysis, John Wiley & Sons, 1995.
Coussy, O., Mécanique des milieux poreux, Editions Technip, 1991, Paris.
Liu, G. R., Nguyen Thoi Trung, Smoothed Finite Element Methods, CRC Press, 2010.
Schneider F., Modelling multi-phase flow of petroleum at the sedimentary basin scale. Journal of Geochemical exploration 78-79 (2003) 693-696).
Steckler, M. S., and A. B. Watts, Subsidence of the Atlantic-type continental margin off New York, Earth Planet. Sci. Lett., 41, 1-13, 1978.
Zienkiewicz, O. C., Taylor, R. L., The finite element method—Volume 1: the basis—Fifth Edition, Butterworth Heinemann, 2000.

Basin simulation tools allowing to numerically simulate the formation of a sedimentary basin are known. Examples thereof are the tools described in patent EP-2,110,686 (U.S. Pat. No. 8,150,669) or in patent applications EP-2,816,377 (US-2014/0,377,872), EP-3,075,947 (US-2016/0,290,107), EP-3,182,176 (US-2017/0,177,764). These tools notably allow to assess the evolution of quantities such as temperature and pressure in the entire sedimentary basin over geological times, and thus to simulate, over geological times, both the transformation of the organic matter present in a source rock of the basin into hydrocarbons and the migration, into a reservoir rock of the basin, of the hydrocarbons thus produced.

Conventionally, as described for example in the document (Schneider, 2003), basin simulation softwares assume only vertical variations of the mechanical stresses that affect a sedimentary basin. More precisely, basin simulation softwares only take into account the vertical component of the mechanical stress variations induced by the weight of the successive sediment deposits in the course of time. This is referred to as 1D mechanical effects simulation.

However, a sedimentary basin can undergo, throughout its history, mechanical stresses characterized by components in the three dimensions of space, and these stresses may be local or regional, and time variant. These mechanical stresses are on the one hand induced by the sediment deposits themselves. In this case, the mechanical stresses involve a vertical component, related to the weight of the sediments on the already deposited layers, but they also often have horizontal components, as well as shear components as the sediment deposits are generally not invariant laterally. On the other hand, a sedimentary basin undergoes, throughout the formation thereof, mechanical stresses induced by tectonic movements related to the geodynamics of the Earth, such as extension movements (causing opening of the basin with, for example, rift formation) or compression movements (causing folds, overlaps, fractures within the basin, etc.). These tectonic movements most often induce mechanical stress variations in the three dimensions of space. It is noted that an already deposited layer undergoes stress variations induced by the tectonic movements undergone by a sedimentary basin throughout the formation thereof.

Thus, in the case of such basins, high-precision modelling of the stress field is required, and the vertical model is no longer satisfactory. Document EP-3,182,176 (U.S. Pat. No. 10,296,679) describes a coupling between a conventional basin simulator (i.e. with 1D simulation of the mechanical effects) and a mechanical simulator allowing to determine and to take into account the displacement and stress field in 3 dimensions in a basin modelling simulation. The coupling described in this document allows to carry out the thermal, hydrodynamic and mechanical computations with a single mesh.

In general terms, the meshes used in basin simulation must be hexahedral-dominant (or hex-dominant) and consistent with the boundaries between stratigraphic layers so that hydrodynamic modelling is as precise as possible. Now, sometimes, some basins comprise a succession of very fine geological layers (a few meters, whereas the conventional dimensions of a basin model are of the order of a hundred km in the two horizontal directions and of the order of 10 to 20 km in the vertical direction) having very heterogeneous mechanical and hydraulic properties and/or pinched-out stratigraphic layers, and these characteristics need to be taken into account in the mesh representation of the basin for a precise numerical simulation.

Fine layers and pinchouts are two geometric objects that make the generation of the mesh to be used for basin modelling very complex, notably for mechanical behaviour simulation. Conventionally, simulation of the mechanical behaviour is performed with the finite-element method (FEM). The quality of the solution that can be obtained with this method depends on the size of the mesh cells (accuracy increases with mesh refinement) and on the shape thereof. Ideally, the geometry of the cell must be regular and its aspect ratio (ratio between the lengths of the smallest edge and the greatest edge thereof) should be 1: a hexahedral cell should ideally be a cube, a tetrahedral cell should ideally be a regular tetrahedron, etc. In the presence of fine layers and pinchouts, compliance with these conditions would inevitably lead to the generation of meshes with a very large number of cells, thus making the algorithms using these meshes unusable due to the excessive increase in memory and computation time demand. In the case of pinchouts, it is even impossible to comply with the condition on the cell geometry, even when significantly increasing the mesh refinement: the presence of very low angles at the end of the pinchout shows flattened or distended cells, regardless of the refinement level. In some cases, the unfavourable geometry of these cells generates numerical problems that prevent successful simulation.

In practice, in case of fine layers or stratigraphic pinchouts, in order to limit the number of cells to be used for numerical simulation, cells having a lateral extension of one to several kilometers are conventionally used, whereas it is only a few meters in the vertical direction. Besides, the presence of stratigraphic pinchouts further requires being able to process cells whose faces are connected at a very low angle, of the order of 1° for example. Thus, some practical application cases of numerical basin simulation do not enable generation of a mesh where the conditions relative to the cell shape are verified, which results in that the quality of the numerical basin simulation is not guaranteed. In some cases, it may even occur that the numerical method cannot find a solution.

In order to overcome these drawbacks, it is possible to use the FS-FEM method (Face-based Smoothed Finite-Element Method). The FS-FEM method is a variation of the S-FEM method (Smoothed Finite-Element Method), which is itself a variant of the FEM method. Each variation of the S-FEM method has its convergence and accuracy properties. The FS-FEM variant is known as the most accurate variation of the S-FEM method.

However, as shown hereafter, it appears that application of the FS-FEM method to solve the balance equation of poromechanics is unstable in the case of a hex-dominant mesh having flattened cells (ratio of the smallest vertical edge to the greatest vertical edge 1/5 at most, preferably 1/10). Now, in practice, in order not to disproportionately increase the number of cells of the numerical basin simulation, the fine layers and the stratigraphic pinchouts are often represented by flattened cells.

The present invention aims to overcome these drawbacks. In particular, the present invention allows to solve numerically, in a stable manner that guarantees the quality of the solution, the equations involved in a numerical basin simulation, in particular the balance equation of poromechanics by means of a face-based smoothed finite-element method, even in case of a hex-dominant mesh representing fine layers and/or stratigraphic pinchouts.

### SUMMARY OF THE INVENTION

The present invention relates to a computer-implemented method of modelling a sedimentary basin, said sedimentary basin having undergone a plurality of geological events defining a sequence of states of said basin, by means of a computer-executed numerical basin simulation, said numerical basin simulation solving at least a balance equation of poromechanics according to a face-based smoothed finite-element method for determining at least a stress field and a strain field. The method according to the invention comprises at least the following steps:

A. performing physical quantity measurements relative to said basin by means of sensors and constructing a mesh representative of said basin for each of said states of said basin, said meshes of said basin for each of said states predominantly consisting of hexahedral cells,

B. by means of said numerical basin simulation and said meshes for each of said states, determining at least a strain field and a stress field for each of said states by carrying out at least the following steps for each of said meshes of said states:

a) subdividing each of said hexahedral cells of said mesh into at least eight hexahedral subcells,

b) for each face of each of said subcells, determining a smoothing domain according to the face-based smoothed finite-element method applied to said subcells,

c) for each of said smoothing domains, determining a strain-displacement relation according to the face-based smoothed finite-element method applied to said smoothing domains,

d) for each of said smoothing domains, determining a transition relation between the degrees of freedom of the nodes of said subcells containing said smoothing domain and the degrees of freedom of the nodes of said at least one cell to which said subcells belong,

e) determining a stiffness and nodal forces for each of said smoothing domains from at least said transition relation determined for said smoothing domain and from said strain-displacement relation determined for said smoothing domain,

f) determining a stiffness and nodal forces relative to said mesh from at least said stiffness and said nodal forces determined for each of said smoothing domains,

g) modelling the sedimentary basin by determining at least said displacement field and said stress field for said mesh, by means of said numerical basin simulation and at least of said stiffness and said nodal forces determined for said mesh.

According to an implementation of the invention, each of said hexahedral cells of said mesh can be subdivided into eight hexahedral subcells, said subdivision of one of said cells being performed in such a way that each face of said cell consists of four faces of four subcells among said eight subcells.

According to an implementation of the invention, it is possible, in step b), to determine said smoothing domain relative to one of said faces belonging to at least one of said subcells by connecting each node of said face with at least one point located at the barycenter of the subcell(s) to which said face belongs.

According to an embodiment of the invention, said strain-displacement relation can be a transformation matrix relating a displacement vector to a strain vector according to a formula of the type:

$$B = [ {B}_{1} {B}_{2} … {B}_{n - 1} {B}_{n} ]$$

$$with {B}_{i} = \frac{1}{\text{?}} \int \text{?} {nN}_{i} dT$$

$$\text{?} \text{indicates text missing or illegible when filed}$$

where Bᵢ is a matrix respectively associated with node i, with i=1 . . . n, of said subcell(s) to which said smoothing domain nₖ^{s} belongs, Aₖ^{s} is the volume of said smoothing domain Ωₖ^{s}, ∂Ωₖ^{s} is a boundary of said smoothing domain, n is an outward normal of said smoothing domain Ωₖ^{s} and Nᵢ is a shape function associated with node i.

According to an implementation of the invention, said transition relation for a smoothing domain relative to one of said faces of at least one of said subcells can be a transition matrix determined according to at least the shape function matrices of the finite element assigned to said subcell(s) to which said smoothing domain belongs, said shape function matrices being evaluated at each node of said subcell(s) to which said smoothing domain belongs.

According to an implementation of the invention, said stiffness and said nodal forces for each of said smoothing domains can take the form of a stiffness matrix and a nodal force vector respectively, and said stiffness matrix K_{Ωvirt} and said nodal force vector f_{Ωvirt} for one of said smoothing domains Ωᵥᵢᵣₜ can be respectively determined according to formulas of the type:

K_{Ω}_{ᵥᵢᵣₜ}=∫_{Ω}_{ᵥᵢᵣₜ}T_{Ω}_{ᵥᵢᵣₜ}^{T}B_{Ω}_{ᵥᵢᵣₜ}^{T}DB_{Ω}_{ᵥᵢᵣₜ}T_{Ω}_{ᵥᵢᵣₜ}dV

f_{Ω}_{ᵥᵢᵣₜ}=−∫_{Ω}_{ᵥᵢᵣₜ}N^{T}bdV−∫_{BΩ}_{ᵥᵢᵣₜ}N^{T}t̅dA−∫_{Ω}_{ᵥᵢᵣₜ}T_{Ω}_{ᵥᵢᵣₜ}^{T}B_{Ω}_{ᵥᵢᵣₜ}^{T}Dε₀dV+∫_{Ω}_{ᵥᵢᵣₜ}T_{Ω}_{ᵥᵢᵣₜ}^{T}B_{Ω}_{ᵥᵢᵣₜ}^{T}σ₀dV

wherein T_{Ωvirt} is said transition matrix for said smoothing domain Ωᵥᵢᵣₜ, B_{Ωvirt} is said transformation matrix for said smoothing domain Ωᵥᵢᵣₜ, N is a matrix of said shape functions, D is a matrix representative of the material stiffness, b is a body force vector, t is a surface force vector, ε₀ is an initial strain and σ₀ is an initial residual stress.

According to an implementation of the invention, it is possible in step f), if all of said cells of said mesh are hexahedral, to determine said stiffness and said nodal forces relative to said mesh according to respective formulas of the type:

K=Σᵢ₌₁^{nv}K_{Ω}_{_{virt t}}

f=Σᵢ₌₁^{nv}f_{Ω}_{_{virt t}}

where nv is the total number of said smoothing domains.

Furthermore, the invention relates to a computer program product downloadable from a communication network and/or recorded on a computer-readable medium and/or processor executable, comprising program code instructions for implementing the method as described above, when said program is executed on a computer.

The invention also relates to a method for exploiting hydrocarbons present in a sedimentary basin, said method comprising at least implementing the method for modelling said basin as described above, and wherein, from at least said modelling of said sedimentary basin, an exploitation scheme is determined for said basin, comprising at least one site for at least one injection well and/or at least one production well, and said hydrocarbons of said basin are exploited at least by drilling said wells of said site and by providing them with exploitation infrastructures.

### BRIEF DESCRIPTION OF THE FIGURES

Other features and advantages of the method according to the invention will be clear from reading the description hereafter of embodiments, given by way of non-limitative example, with reference to the accompanying figures wherein:

FIG. 1 shows an illustrative example of a sedimentary basin,

FIG. 2 shows an example of a sedimentary basin (left) and an example of a mesh representation (right) of this basin,

FIG. 3 shows an example of structural reconstruction of a sedimentary basin according to an embodiment of the invention, represented by three strain states taken in three different geological states,

FIG. 4 shows the strain in a beam subjected to bending, calculated with the FEM method and the FS-FEM method, in the case of flattened hexahedral cells,

FIG. 5 shows an example of subdivision of a hexahedral cell into eight hexahedral subcells, and

FIG. 6 illustrates the construction of a smoothing domain according to the invention for a face belonging to two subcells.

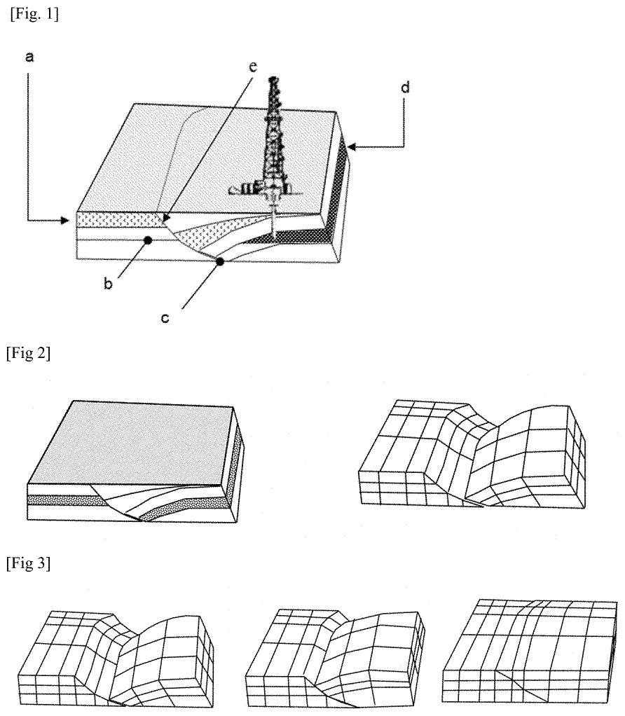

### DETAILED DESCRIPTION OF THE INVENTION

According to a first aspect, the invention relates to a computer-implemented method of modelling a sedimentary basin, by means at least of a numerical basin simulation solving at least a balance equation of poromechanics according to a face-based smoothed finite-element method known as FS-FEM method.

In general terms, the balance equation of poromechanics is written (see for example document (Coussy, 1991)):

∇·σ′+(ρ+m)g=∇·(pB)

where σ′ is the effective stress tensor, ρ the homogenized density of the porous medium, m the fluid mass exchange, g the acceleration of gravity, p the fluid pressure and B the Biot tensor. In a numerical simulation such as a basin simulation, this equation is numerically solved. In general, this equation is usually discretized in a mesh representation (or mesh) by means of the finite-element method (FEM) or one of its variants such as, for example, the smoothed finite-element method (S-FEM).

Different variations of the S-FEM method exist in the literature in the field of mechanical simulation, each with its convergence and accuracy properties. The variation known as FS-FEM (Face-based Smoothed Finite-Element Method) is known as the most accurate variation of the S-FEM method. However, in the literature, the FS-FEM method is described to date only for tetrahedral cells, and all the application cases found in the literature in the field of mechanical simulation use a tetrahedral mesh only.

The applicant has observed that the FS-FEM method is in practice unstable in the case of a mesh having very flattened hexahedral cells. It therefore appears that the FS-FEM method cannot be applied as is in the case of basin models whose mesh representation comprises cells representative of thin geological layers (for example of the order of a few meters in the vertical direction) and/or when these layers comprise stratigraphic pinchouts (characterized by an angle less than 1°).

The instability of the FS-FEM method in the presence of flattened hexahedral cells (i.e. whose ratio of the greatest horizontal edge to the smallest vertical edge is at least 5, preferably 10) materializes in two different ways in numerical simulations: either the computation stops with a fatal error because the stiffness matrix of the model is singular (zero determinant), which means that it cannot be inverted, or the computed solution is incorrect and it locally exhibits oscillations and/or peaks in the computed displacements, stresses and strains. An example of the latter case is shown in FIG. 4, within the context of a beam subjected to bending, the beam being represented by cells consisting of flattened hexahedra (aspect ratio 1:10). More precisely, FIG. 4, top, shows the geometry of the deformed beam computed with the FEM method. This deformed shape is correct because it is coherent with the known analytical solution to the problem. FIG. 4, bottom, shows the deformed beam geometry obtained with the FS-FEM method: the strain is clearly incorrect and the accordion shape is the typical sign of numerical instability (see also paragraph 4.6 of document (Cook, 1995)).

The present invention relates to an improvement to the FS-FEM method in order to make it applicable to the hexahedral cells used in basin models. More specifically, in a particularly shrewd manner, the applicant has shown that improving the FS-FEM method according to the invention allows to stabilize the numerical simulation, including in the case of flattened hexahedral cells.

Thus, the numerical basin simulation according to the invention aims to solve numerically at least the balance equation of poromechanics according to the face-based smoothed finite-element method (FS-FEM) in the case of a hex-dominant mesh representation.

In general terms, discretization of the balance equation of poromechanics leads to write a system of algebraic equations of the following form (see for example Equation 2.23 of the document (Zienkiewicz and Taylor, 2000)):

Ka+f=r (1)

where K is the stiffness matrix of the system, a is the vector of the degrees of freedom of the nodes of the mesh used for discretization (nodal displacements, see Equation 2.1 of the document (Zienkiewicz and Taylor, 2000)), f is a vector of the nodal forces (equivalent nodal forces, see Equation 2.24B of the document (Zienkiewicz and Taylor, 2000)), and r is the vector of the external concentrated forces (see Equation 2.14 of the document (Zienkiewicz and Taylor, 2000)). Details of the solution of this system of equations by means of a face-based smoothed finite-element method specifically suited to the case of hexahedral cells are given in step 2 of the method according to the invention.

According to the invention, it is assumed that the sedimentary basin has undergone a plurality of geological events defining a sequence of states of the basin, each of said states extending between two successive geological events. Preferably, the sequence of states can cover a period of time covering at least the production of hydrocarbons, notably by maturation of an organic matter present in a source rock of the basin, deformation of the basin due to 3D mechanical stresses, displacement of these produced hydrocarbons into at least one reservoir rock of the basin over geological times. By way of non-limitative example hereafter, Ai denotes a state of the sequence of states of the basin, i being an integer ranging from 1 to n, An representing the state of the basin at the current time. According to the invention, n is at least 2. In other words, the sequence of states according to the invention comprises the state of the basin at the current time and at least one state of said basin at an earlier geological time.

According to a second aspect, the invention relates to a method of exploiting hydrocarbons present in a sedimentary basin, the method according to the second aspect comprising implementing the method of modelling a sedimentary basin according to the first aspect of the invention.

The method according to the first aspect of the invention comprises at least steps 1) and 2) described hereafter.

The method according to the second aspect of the invention comprises at least steps 1) to 3) described hereafter.

### 1) Constructing Mesh Representations for Each of the States

This step consists in measuring physical quantities relative to the basin by means of sensors and in constructing a mesh representative of the basin at the current time, then meshes for each state of the basin. According to the invention, the mesh representations of the basin for each of said states predominantly consist of hexahedral cells. This is conventionally known as hex-dominant meshing.

During this step, at least the three following substeps are carried out:

1.1) Measuring Physical Quantities Relative to the Basin

This substep consists in acquiring physical quantity measurements relative to the basin studied, by means of sensors.

By way of non-limitative example, the sensors can be logging tools, seismic sources and receivers, fluid samplers and analyzers, etc.

Thus, the measurements according to the invention can consist of outcrop surveys, seismic acquisition surveys, measurements in wells (logging for example), petrophysical and/or geochemical analyses of core samples taken in situ.

These measurements allow to deduce petrophysical properties associated with the basin studied, such as facies (lithology), porosity, permeability, or the organic matter content at measuring points of the basin. Information relative to the properties of the fluids present in the basin can also be obtained, such as saturation values of the various fluids present in the basin. Temperatures can also be measured at different points of the basin (notably bottomhole temperatures).

1.2) Constructing a Mesh Representative of the Basin at the Current Time

This substep consists in constructing a hex-dominant mesh representative of the basin at the current time, from the physical quantity measurements performed in the previous substep.

More precisely, construction of a mesh representation of a basin consists in discretizing in three dimensions the architecture of the basin and in assigning properties to each of the cells of this mesh. The physical quantity measurements performed at various points of the basin as described above are therefore notably exploited, extrapolated and/or interpolated, in the various cells of the mesh, according to more or less restrictive hypotheses.

Most often, the spatial discretization of a sedimentary basin is organized in cell layers representing each the various geological layers of the basin studied. FIG. 2 illustrates, on the left side, an example of a sedimentary basin at the present time and, on the right side, an example of a mesh of this basin.

According to an implementation of the invention, the mesh constructed for the current state An of the basin studied notably comprises in each cell information on the lithology, a porosity value, a permeability value, an organic matter content, and properties relative to the fluids present in the cell, such as saturation.

According to an implementation of the invention, the mesh constructed for the current state An of the basin predominantly consists of hexahedral cells. The OpenFlow® software (IFP Energies nouvelles, France) or the GOCAD® software (Emerson-Paradigm, USA) can be used.

1.3) Structural Reconstruction of the Basin Architecture for the Various States

This substep consists in reconstructing the past architectures of the basin for the various states Ai, with i ranging from 1 to n−1. The mesh constructed in the previous substep, which represents the basin at the current time, is therefore deformed in order to represent the anti-chronological evolution of the subsoil architecture over geological times, and for the various states Ai. At the end of this substep, a mesh is available for each state Ai, with i ranging from 1 to n.

According to a first embodiment of the present invention, structural reconstruction can be particularly simple if it is based on the assumption that its deformation only results from a combination of vertical movements by compaction of the sediment or by uplift or downwarping of its basement. This technique, known as backstripping, is described in (Steckler and Watts, 1978) for example.

According to another embodiment of the present invention, in the case of basins whose tectonic history is complex, notably in the cases of basins with faults, less restrictive hypotheses, such as structural restoration, need to be used. Such a structural restoration is described for example in document FR-2,930,350 A1 (US-2009/0,265,152 A1). Structural restoration consists in computing the successive deformations undergone by the basin by integrating the deformations due to compaction and those resulting from tectonic forces.

In the example of FIG. 3, three states are used to represent the subsoil deformation over geological times. The mesh on the left represents the current state, where a slip interface (a fault here) can be observed. The mesh on the right represents the same sedimentary basin for a state Ai, prior to the current state. For this state Ai, the sedimentary layers are not fractured yet. The central mesh represents an intermediate state, i.e. the sedimentary basin in a state Ai′ between state Ai and the current state. It is observed that the slip along the fault has started to modify the basin architecture.

### 2) Determining a Strain and Stress Field by Numerical Basin Simulation for Each State

In this step, by means of numerical basin simulation and of the meshes determined for each of the states in the previous step, at least one strain field and one stress field are determined for each state, by carrying out at least substeps 2.1 to 2.5 and substeps 2.7 to 2.8 described below for each of the states. In other words, at least substeps 2.1 to 2.5 and substeps 2.7 to 2.8 described below are applied for each mesh representative of a state of the basin studied.

According to the invention, substeps 2.1 to 2.5 are only applied to the hexahedral cells of the meshes of each state. According to an implementation of the invention, when the mesh representing any state comprises both hexahedral cells and cells of another type, substep 2.6 can be applied to the cells of another type than the hexahedral type. According to the invention, substeps 2.7 and 2.8 are applicable whatever the cell type of the mesh representative of a state.

2.1) Subdividing the Hexahedral Cells of the Mesh

This substep consists in subdividing each of the hexahedral cells (also referred to as parent cells hereafter) of the mesh considered into at least eight hexahedral subcells (also referred to as virtual cells hereafter). It is clear that the non-hexahedral cells of the mesh considered are not subdivided as described in this substep. Processing of the other cell types of the mesh than the hexahedral type is detailed hereafter in substep 2.6.

According to a preferred embodiment of the invention, each hexahedral cell of the mesh can be subdivided into eight hexahedral subcells, subdivision being performed in such a way that each face of the parent cell consists of four faces of four subcells among the eight subcells.

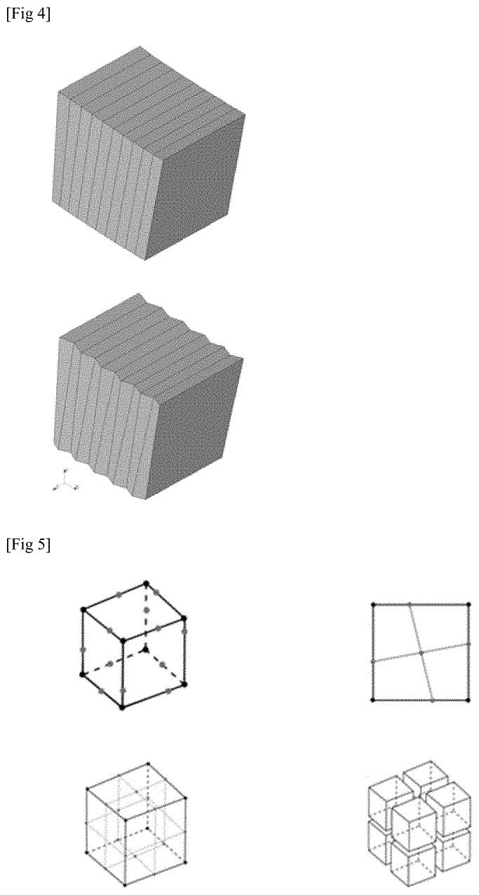

According to this preferred embodiment of the invention, subdividing a hexahedral cell into eight hexahedral subcells can be performed as follows:
dividing each edge of the parent cell into two edges of any length. The point in common between the two edges thus formed is referred to as virtual node and the other end of each edge, which coincides with one of the corners (real node) of the parent cell, is referred to as real node. An illustrative example of subdividing edges of a hexahedral cell is shown in FIG. 5, top left, where a black point represents a real node and a grey point represents a virtual node,
subdividing each face of the parent cell into quadrangles, from the virtual nodes created by subdividing the edges and by adding an additional virtual node inside the face considered (or, in other words, not on an edge). An illustrative example of subdividing a face of a hexahedral cell into quadrangles is shown in FIG. 5, top right, where a quadrangle is formed by a part (between a real node and a virtual node) of two edges of the parent cell and by two edges (represented by a dotted grey line between two virtual nodes), one of these virtual nodes being located inside the face,
from the quadrangles thus created and by adding an additional virtual node inside the cell (or, in other words, not on a face), from a given quadrangle (also referred to as base face), constructing a subcell (or virtual cell) using the quadrangle selected, the adjacent quadrangles that are not coplanar with the base face and the faces of three other subcells (or virtual cells). An illustrative example of subcell construction is shown in FIG. 5, bottom left. The subcells are thus created on the basis of both real and virtual nodes. It is observed that each face of the parent cell consists of four faces of four subcells.

FIG. 5, bottom right, shows the final result of the subdivision of a parent cell into eight subcells (or virtual cells) according to this preferred embodiment of the invention. The subcells are represented here in a disjoint manner to improve the clarity of the figure, it is however clear that two neighbouring subcells share a common face.

This substep is repeated for each hexahedral cell of the mesh representative of a state.

2.2) Determining a Virtual Smoothing Domain for Each Face of Each Subcell

In this substep, for each face of each of the subcells as determined in the previous substep, a smoothing domain is determined according to the face-based smoothed finite-element method applied to the subcells. These domains are hereafter referred to as “virtual smoothing domains” (and denoted by Ωᵥᵢᵣₜ) because they are constructed from the virtual cells alone. “Applied to the subcells” means that the face-based smoothed finite-element method is applied as described in general terms in the literature, but by considering the hexahedral subcells as determined above, whereas the smoothed finite-element method is usually described for an application to cells. The difference between a subcell and a cell is not geometrical: both are hexahedral cells, but the nodes defining a subcell comprise both virtual and real nodes, whereas those defining a cell are real nodes exclusively. The difference between a real node and a virtual node is that the degrees of freedom of the problem (vector a in Equation (1) above) are associated only with the real nodes. No degree of freedom being associated with a virtual node, the virtual smoothing domains according to the invention require additional processing in relation to what is done for a smoothing domain of a real cell (parent cell in this case), and therefore in relation to what is described in the literature for the smoothed finite-element method. This additional processing is described in substep 2.4 below.

In general terms, the face-based smoothed finite-element method (FS-FEM) and, more generally, the smoothed finite-element method (S-FEM) use, in the mechanical balance formulation, a smoothed strain calculated by a weighted average of the strain according to an equation of the type (see for example Equation 4.19 of document (Liu and Nguyen Thoi Trung, 2010)):

$$\overline{ɛ} ( {x}_{k} ) = \frac{1}{{A}_{k}^{s}} {\int }_{{Ω}_{k}^{s}} \tilde{ɛ} ( x ) d Ω , \qquad ( 2 )$$

where ε̅ is the smoothed strain of the S-FEM method or of the FS-FEM method, \tilde{ε} is the strain (used by the FEM method) and Aₖ^{s} is the volume of a smoothing domain Ωₖ^{s} at on which the strain is smoothed.

According to these methods, whose description can be found in document (Liu and Nguyen Thoi Trung, 2010), Equation (2) above is calculated in each smoothing domain Ωₖ^{s}. The smoothing domains for the S-FEM method, the FS-FEM method or the smoothing domains according to the invention are determined in such a way that:
the smoothing domains cover the mesh entirely,
there is no overlap between the domains.

According to an implementation of the invention, at least one smoothing domain associated with a face belonging to one or two subcells is constructed by connecting each node (real or virtual) of the face considered with at least one point located at the barycenter of the subcell(s) to which the face belongs.

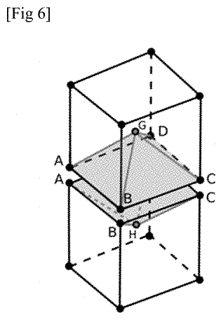

FIG. 6 illustrates the construction of such a smoothing domain for a face belonging to two subcells. Thus, the smoothing domain associated with face ABCD, which is common to two subcells, is constructed by connecting each node A, B, C, D of the face with the barycenter G and I of each subcell. The resulting smoothing domain, in grey in the figure, consists of two pyramids A BCDG and ABCDH.

It is clear that, for a face of a hexahedral subcell located on the borders of a mesh, i.e. a face belonging to a single subcell (in other words, a free face), the smoothing domains consists of a single pyramid because the nodes of a face can only be connected to one barycenter.

2.3) Determining a Strain-Displacement Relation for Each Virtual Smoothing Domain

In this step, for each of the virtual smoothing domains as determined in the previous substep, a strain-displacement relation is determined according to the face-based smoothed finite-element method applied to the virtual smoothing domains as determined above. “Applied to the smoothing domains” means that the face-based smoothed finite-element method is applied as described in general terms in the literature, but by considering the smoothing domains as determined above, i.e. for hexahedral subcells.

According to an implementation of the invention, said strain-displacement relation takes the form of a matrix relating the displacement vector to the strain vector. This matrix is also referred to as strain-displacement transformation matrix.

According to an implementation of the invention, using Equation (2) above for the definition of the smoothed strain leads to the following expression for the strain-displacement transformation matrix, denoted by B (see also Equations 4.29, 4.30 and 4.31 in document (Liu and Nguyen Thoi Trung, 2010)):

$$\begin{matrix} B = [ {B}_{1} {B}_{2} … {B}_{n - 1} {B}_{n} ] & ( 3 ) \\ with & \\ {B}_{i} = \frac{1}{\text{?}} \int \text{?} {nN}_{i} dT & ( 4 ) \\ \text{?} \text{indicates text missing or illegible when filed} & \end{matrix}$$

where B₁ . . . Bₙ are the matrices respectively associated with nodes i=1 . . . n of the subcell(s) to which smoothing domain Ωₖ^{s} belongs, Aₖ^{s} is the volume of smoothing domain Ωₖ^{s}, ∂Ωₖ^{s} is the boundary of the smoothing domain, n is the outward normal of smoothing domain Ωₖ^{s} and Nᵢ is a shape function (see paragraph 2.2.1 of document (Zienkiewicz and Taylor, 2000)) associated with node i.

2.4) Determining a Transition Relation Between the Degrees of Freedom of the Subcell Nodes and of the Cell Nodes for Each Virtual Smoothing Domain

This substep, which is applied for each of the smoothing domains determined as described above, consists in determining a transition relation between the degrees of freedom of the nodes (located at the ends of the subcell edges), real or virtual, of the subcell(s) containing the smoothing domain considered and the degrees of freedom of the nodes of the (parent) cell(s) to which the subcell(s) considered belong.

According to an implementation of the invention, said transition relation can take the form of a transformation matrix or a transition matrix. According to this implementation of the invention, this transition matrix allows to express the degrees of freedom of the nodes (real or virtual) of the virtual cells in relation to the degrees of freedom of the real nodes of the parent cells of the mesh.

According to an implementation of the invention, the transition matrix relative to a smoothing domain is determined according to at least shape function matrices of the finite element assigned to the cell(s) to which said smoothing domain belongs, the shape function matrices being evaluated at each node of the subcell(s) to which said smoothing domain belongs.

According to an implementation of the invention, this substep is carried out for a virtual smoothing domain Ωᵥᵢᵣₜ as follows:

a) determining the subcell(s) i containing the smoothing domain considered. If the face on which the smoothing domain considered was generated is a free face (i.e. if the face is located on the border of the mesh), the smoothing domain is contained in a single subcell (and we note i=1 hereafter). If the face is common to two subcells, the smoothing domain is contained in two subcells (and we note i=1, 2 hereafter),

b) for each subcell i (i=1 or i=1, 2) thus identified, calculating a transition matrix Tᵢ by means of the shape functions N of the parent cell that contains the subcell considered according to a formula of the type (see Equation 2.1 of document (Zienkiewicz and Taylor, 2000)):

$${T}_{i} = [ \begin{matrix}{N}_{i} ( {x}_{1} ) \\ ⋮ \\ {N}_{i} ( {x}_{m} )\end{matrix} ] \qquad ( 5 )$$

where Nᵢ(x₁) is the shape function matrix (see paragraph 2.2.1 of document (Zienkiewicz and Taylor, 2000)) of the finite element assigned to the parent cell that contains subcell i (i=1 or i=1, 2) evaluated at node j of subcell i, with j=1 . . . n, and n being the number of nodes (real and virtual) of subcell i,

c) in the case of a free face (i=1), transition matrix T_{Ωvirt} relative to virtual smoothing domain Ωᵥᵢᵣₜ is equal to matrix Tᵢ as determined above; otherwise, transition matrix T_{Ωvirt} relative to virtual smoothing domain Ωᵥᵢᵣₜ is constructed from the two matrices Tᵢ calculated above according to a formula of the type:

$${T}_{{Ω}_{virt}} = [ \begin{matrix}{T}_{1} \\ {T}_{2}\end{matrix} ] \qquad ( 6 )$$

2.5) Determining a Stiffness and Nodal Forces for Each Virtual Smoothing Domain

This substep consists in determining a stiffness and nodal forces for each of the smoothing domains determined as described above, from at least the transition relation determined for the smoothing domain considered as described above and the strain-displacement relation determined for this smoothing domain as described above.

According to an implementation of the invention, said stiffness and said nodal forces can take the form of a stiffness matrix and of a nodal force vector respectively.

According to an implementation of the invention, stiffness matrix K_{Ωvirt} and nodal force vector f_{Ωvirt} are determined for a virtual smoothing domain Ωᵥᵢᵣₜ as follows:

K_{Ω}_{ᵥᵢᵣₜ}=∫_{Ω}_{ᵥᵢᵣₜ}T_{Ω}_{ᵥᵢᵣₜ}^{T}B_{Ω}_{ᵥᵢᵣₜ}^{T}DB_{Ω}_{ᵥᵢᵣₜ}T_{Ω}_{ᵥᵢᵣₜ}dV (7)

f_{Ω}_{ᵥᵢᵣₜ}=−∫_{Ω}_{ᵥᵢᵣₜ}N^{T}bdV−∫_{BΩ}_{ᵥᵢᵣₜ}N^{T}t̅dA−∫_{Ω}_{ᵥᵢᵣₜ}T_{Ω}_{ᵥᵢᵣₜ}^{T}B_{Ω}_{ᵥᵢᵣₜ}^{T}Dε₀dV+∫_{Ω}_{ᵥᵢᵣₜ}T_{Ω}_{ᵥᵢᵣₜ}^{T}B_{Ω}_{ᵥᵢᵣₜ}^{T}σ₀dV (8)

wherein transformation matrix T_{Ω}_{ᵥᵢᵣₜ} is the transition matrix determined as described in substep 2.4, B_{Ω}_{ᵥᵢᵣₜ} is a strain-displacement transformation matrix determined as described in substep 2.3, N is the shape function matrix of the finite element of the parent cell as described above, D is a matrix representative of the material stiffness, b is the body force vector, t̅ the surface force vector (distributed external loading), ε₀ the initial strain (see paragraph 2.2.3 of document (Zienkiewicz and Taylor, 2000)) and σ₀ the initial residual stress (see paragraph 2.2.3 of document (Zienkiewicz and Taylor, 2000)).

2.6) Determining a Stiffness and Nodal Forces for Non-Hexahedral Cells

This substep is optional and it can be applied in cases where the mesh representative of the state of the basin considered is a hex-dominant mesh, predominantly comprising hexahedral cells, but also comprising a minority of other types of cell (such as tetrahedral, pyramidal, pentahedral cells, etc.).

In this case, the face-based smoothed finite-element method as described in document (Liu and Nguyen Thoi Trung, 2010) can be applied to the other cell types of the mesh. Applying this method to the other cell types leads to define smoothing domains for each face of these cells (without cell subdivision) and to determine a stiffness matrix (denoted by K_{Ω} hereafter) and a nodal force vector (denoted by f_{Ω} hereafter) for each smoothing domain relative to each of the faces of the other cell types of the mesh.

According to an implementation of the invention, a smoothing domain for a face belonging to one or two cells of another type than the hexahedral type can be constructed by connecting each node of the face considered with at least one additional point located at the barycenter of the cell(s) to which the face belongs.

According to an implementation of the invention, when a face is common to a hexahedral subcell and a cell of another type, this face is considered as a free face for the construction of smoothing domains. In other words, for such a face, two smoothing domains are constructed, a first one on the side of the hexahedral subcell and a second on the side of the cell of another type, each smoothing domain being constructed by connecting each node of the face considered to the barycenter of the cell to which the node belongs.

According to an implementation of the invention, stiffness matrix K_{Ω} and nodal force vector f_{Ω} relative to a smoothing domain constructed for non-hexahedral cells can be determined by means of Equations 2.24a and 2.24b of document (Zienkiewicz and Taylor, 2000) and by using the definition of the strain-displacement transformation matrix denoted by B, described in Equation 3.67 of document (Liu and Nguyen Thoi Trung, 2010).

2.7) Determining a Stiffness and Nodal Forces for the Mesh

This substep consists in determining a stiffness and nodal forces relative to the mesh representative of the state considered from at least the stiffness and the nodal forces determined for each virtual smoothing domain defined as described above for this mesh.

According to an implementation of the invention wherein the stiffness and/or the nodal forces can take the form of a stiffness matrix and a nodal force vector respectively, stiffness matrices K_{Ωvirt} and vectors f_{Ωvirt} determined for each virtual smoothing domain Ωᵥᵢᵣₜ in the previous substep are assembled by means of a standard assembly used in the finite-element method (see paragraph 1.3 of document (Zienkiewicz and Taylor, 2000)), which can be written as follows:

K=Σᵢ₌₁^{nv}K_{Ω}_{_{virt t}} (9)

f=Σᵢ₌₁^{nv}f_{Ω}_{_{virt t}} (10)

where nv is the total number of virtual smoothing domains Ωᵥᵢᵣₜ.

According to an implementation of the invention wherein the mesh representative of the state considered predominantly comprises hexahedral cells and a minority of other types of cell, a stiffness matrix and a nodal force vector are determined for the mesh according to a formula of the type:

K=Σᵢ₌₁^{nv}K_{Ω}_{_{virt t}}+Σᵢ₌₁ⁿK_{Ω}_{ₜ} (11)

f=Σᵢ₌₁^{nv}f_{Ω}_{_{virt t}}+Σᵢ₌₁ⁿf_{Ω}_{ₜ} (12)

where nv is the total number of virtual smoothing domains Ωᵥᵢᵣₜ constructed for the hexahedral cells and n is the total number of smoothing domains Ω constructed for the other cell types as described in substep 2.6.

2.8) Determining the Displacement Field and the Stress Field for the Mesh

This substep consists in modelling the basin studied by determining at least the displacement field and the stress field for the mesh considered, by means of the numerical basin simulation according to the invention and of at least the stiffness and the nodal forces determined for the mesh considered and determined as described in the previous substep.

According to an implementation of the invention, the discretized problem defined by Equation (1) above, implemented in the basin simulator according to the invention and used with stiffness matrix K determined as described above (and computed with Equations (9) or (11) above for example) and nodal force vector f determined as described above (and computed with Equations (10) or (12) above for example), is solved. Determining vector r of Equation (2), which is the boundary conditions vector, can be done using the conventional FEM method, as described for example in paragraph 1.3 of document (Zienkiewicz and Taylor, 2000).

According to the invention, at least substeps 2.1 to 2.5 and substeps 2.6 and 2.7 are repeated for each mesh representative of each state of the basin, substep 2.6 being also repeated in the case of a mesh comprising hexahedral cells and other types of cell.

3) Exploiting the Hydrocarbons of the Basin

This step is carried out within the context of the second aspect of the invention, which concerns a method of exploiting the hydrocarbons present in a sedimentary basin.

After carrying out the previous steps, basin simulation results are available. The basin simulation according to the invention allows at least to determine the basin stress and strain field for various states of the basin, in a stable manner in the case of a hex-dominant mesh some cells of which have a poor aspect ratio.

Implicitly, and as is conventional in basin simulation, the amount of hydrocarbons present in each cell of the mesh representative of the basin for the past and current times is also known.

Furthermore, depending on the basin simulator used for implementing the invention, it is possible for example to have information on:

i. the development of sedimentary layers

ii. their compaction under the effect of the weight of the overlying sediments

iii. their temperature evolution during burial

iv. the changes in fluid pressure resulting from this burial

iv. the thermogenic formation of hydrocarbons.

From such information, the specialist can then determine cells of the mesh representative of the basin at the current time comprising hydrocarbons, as well as the proportion, the nature and the pressure of the hydrocarbons trapped therein. The zones of the basin studied having the best petroleum potential can then be selected. These zones are then identified as reservoirs (or hydrocarbon reservoirs) of the sedimentary basin studied.

This step consists in determining at least one scheme for exploiting the hydrocarbons contained in the sedimentary basin studied. Generally, an exploitation scheme comprises a number, a geometry and a site (position and spacing) for injection and production wells to be drilled in the basin. An exploitation scheme can further comprise a type of enhanced recovery for the hydrocarbons contained in the reservoir(s) of the basin, such as enhanced recovery through injection of a solution containing one or more polymers, CO₂ foam, etc. A hydrocarbon reservoir exploitation scheme must for example enable a high rate of recovery of the hydrocarbons trapped in this reservoir, over a long exploitation time, and requiring a limited number of wells. In other words, the specialist predefines evaluation criteria according to which a scheme for exploiting the hydrocarbons present in a sedimentary basin is considered sufficiently efficient to be implemented.

According to an embodiment of the invention, a plurality of exploitation schemes is defined for the hydrocarbons contained in one or more geological reservoirs of the basin studied, and at least one evaluation criterion is assessed for these exploitation schemes, by means of a reservoir simulator (such as the PumaFlow® software (IFP Energies nouvelles, France)). These evaluation criteria can comprise the amount of hydrocarbons produced for each of the various exploitation schemes, the curve representative of the production evolution over time for each well considered, the gas-oil ratio (GOR) for each well considered, etc. The scheme according to which the hydrocarbons contained in the reservoir(s) of the basin studied are really exploited can then correspond to the one meeting at least one of the evaluation criteria of the various exploitation schemes.

Then, once an exploitation scheme determined, the hydrocarbons trapped in the petroleum reservoir(s) of the sedimentary basin studied are exploited according to this exploitation scheme, notably at least by drilling the injection and production wells of the exploitation scheme thus determined, and by installing the production infrastructures necessary to the development of this or these reservoirs. Moreover, in cases where the exploitation scheme has been determined by estimating the production of a reservoir associated with different enhanced recovery types, the selected additive type(s) (polymers, surfactants, CO₂ foam) are injected into the injection well.

It is understood that a scheme for exploiting hydrocarbons in a basin can evolve during the exploitation of the hydrocarbons of this basin, for example according to additional basin-related knowledge acquired during this exploitation and to improvements in the various technical fields involved in the exploitation of a hydrocarbon reservoir (advancements in the field of drilling, of enhanced oil recovery for example).

Equipment and Computer Program Product

The method according to the invention is implemented by means of an equipment (a computer workstation for example) comprising data processing means (a processor) and data storage means (a memory, in particular a hard drive), as well as an input/output interface for data input and method results output.

The data processing means are configured for carrying out in particular step 2 described above.

Furthermore, the invention concerns a computer program product downloadable from a communication network and/or recorded on a computer-readable medium and/or processor executable, comprising program code instructions for implementing the method as described above, and notably step 2), when said program is executed on a computer.

Thus, the method according to the first aspect of the invention allows to stabilize a numerical basin simulation solving at least one balance equation of poromechanics according to a face-based smoothed finite-element method, in the case of a hex-dominant mesh, even in the case of fine and/or pinched-out geological layers in the sedimentary basin.

Besides, the method according to the second aspect of the invention allows to predict the petroleum potential of complex sedimentary basins, which may have undergone for example complex tectonic movements and exhibit fine layers and/or stratigraphic pinchouts, which contributes to improving the exploitation of hydrocarbons in this type of sedimentary basins.

1. A computer-implemented method of modelling a sedimentary basin, the sedimentary basin having undergone a plurality of geological events defining a sequence of states of the basin, by means of a computer-executed numerical basin simulation, the numerical basin simulation solving at least one balance equation of poromechanics according to a face-based smoothed finite-element method for determining at least a stress field and a strain field, characterized in that the method comprises carrying out at least the following steps:
A. performing physical quantity measurements relative to the basin by means of sensors and constructing a mesh representative of the basin for each of the states of the basin, the meshes representative of the basin for each of the states predominantly consisting of hexahedral cells,
B. by means of the numerical basin simulation and of the meshes for each of the states, determining at least a strain field and a stress field for each of the states by carrying out at least the following steps for each of the meshes representative of the states:
a) subdividing each of the hexahedral cells of the mesh into at least eight hexahedral subcells,
b) for each face of each of the subcells, determining a smoothing domain according to the face-based smoothed finite-element method applied to the subcells,
c) for each of the smoothing domains, determining a strain-displacement relation according to the face-based smoothed finite-element method applied to the smoothing domains,
d) for each of the smoothing domains, determining a transition relation between the degrees of freedom of the nodes of the subcells containing the smoothing domain and the degrees of freedom of the nodes of the at least one cell to which the subcells belong,
e) determining a stiffness and nodal forces for each of the smoothing domains from at least the transition relation determined for the smoothing domain and from the strain-displacement relation determined for the smoothing domain,
f) determining a stiffness and nodal forces relative to the mesh from at least the stiffness and the nodal forces determined for each of the smoothing domains,
g) modelling the sedimentary basin by determining at least the displacement field and the stress field for the mesh, by means of the numerical basin simulation and at least the stiffness and the nodal forces determined for the mesh.

2. A method as claimed in claim 1, wherein each of the hexahedral cells of the mesh is subdivided into eight hexahedral subcells, the subdivision of one of the cells being performed in such a way that each face of the cell consists of four faces of four subcells among the eight subcells.

3. A method as claimed in claim 1 wherein, in step b), the smoothing domain relative to one of the faces belonging to at least one of the subcells is determined by connecting each node of the face with at least one point located at the barycenter of the subcell(s) to which the face belongs.

4. A method as claimed in claim 3, wherein the strain-displacement relation is a transformation matrix relating a displacement vector to a strain vector according to a formula of the type:
$$B = [ {B}_{1} {B}_{2} … {B}_{n - 1} {B}_{n} ]$$
$$with {B}_{i} = \frac{1}{\text{?}} \int \text{?} {nN}_{i} dT$$
$$\text{?} \text{indicates text missing or illegible when filed}$$
where Bᵢ is a matrix respectively associated with node i, with i=1 . . . n, of the subcell(s) to which the smoothing domain Ωₖ^{s} belongs, Aₖ^{s} is the volume of the smoothing domain Ωₖ^{s}, ∂Ωₖ^{s} is a boundary of the smoothing domain, n is an outward normal of the smoothing domain Ωₖ^{s} and Nᵢ is a shape function associated with node i.

5. A method as claimed in claim 4, wherein the transition relation for a smoothing domain relative to one of the faces of at least one of the subcells is a transition matrix determined according to at least the shape function matrices of the finite element assigned to the subcell(s) to which the smoothing domain belongs, the shape function matrices being evaluated at each node of the subcell(s) to which the smoothing domain belongs.

6. A method as claimed in claim 5, wherein the stiffness and the nodal forces for each of the smoothing domains take the form of a stiffness matrix and a nodal force vector respectively, and the stiffness matrix K_{Ωvirt} and the nodal force vector f_{Ωvirt} for one of the smoothing domains Ωᵥᵢᵣₜ are respectively determined according to formulas of the type:
K_{Ω}_{ᵥᵢᵣₜ}=∫_{Ω}_{ᵥᵢᵣₜ}T_{Ω}_{ᵥᵢᵣₜ}^{T}B_{Ω}_{ᵥᵢᵣₜ}^{T}DB_{Ω}_{ᵥᵢᵣₜ}T_{Ω}_{ᵥᵢᵣₜ}dV
f_{Ω}_{ᵥᵢᵣₜ}=−∫_{Ω}_{ᵥᵢᵣₜ}N^{T}bdV−∫_{BΩ}_{ᵥᵢᵣₜ}N^{T}t̅dA−∫_{Ω}_{ᵥᵢᵣₜ}T_{Ω}_{ᵥᵢᵣₜ}^{T}B_{Ω}_{ᵥᵢᵣₜ}^{T}Dε₀dV+∫_{Ω}_{ᵥᵢᵣₜ}T_{Ω}_{ᵥᵢᵣₜ}^{T}B_{Ω}_{ᵥᵢᵣₜ}^{T}σ₀dV
wherein T_{Ωvirt} is the transition matrix for the smoothing domain Ωᵥᵢᵣₜ, B_{Ωvirt} is the transformation matrix for the smoothing domain Ωᵥᵢᵣₜ, N is a matrix of the shape functions, D is a matrix representative of the material stiffness, b is a body force vector, t is a surface force vector, ε₀ is an initial strain and σ₀ is an initial residual stress.

7. A method as claimed in claim 6 wherein, in step f), and if all of the cells of the mesh are hexahedral, the stiffness and the nodal forces relative to the mesh are determined according to respective formulas of the type:
K=Σᵢ₌₁^{nv}K_{Ω}_{_{virt t}}
f=Σᵢ₌₁^{nv}f_{Ω}_{_{virt t}}
where nv is the total number of the smoothing domains.

8. A computer program product downloadable from a communication network and/or recorded on a computer-readable medium and/or processor executable, comprising program code instructions for implementing the method as claimed in claim 1, when the program is executed on a computer.

9. A method for exploiting hydrocarbons present in a sedimentary basin, the method comprising at least implementing the method for modelling the basin as claimed in claim 1, and wherein, from at least the modelling of the sedimentary basin, an exploitation scheme is determined for the basin, comprising at least one site for at least one injection well and/or at least one production well, and the hydrocarbons of the basin are exploited at least by drilling the wells of the site and by providing them with exploitation infrastructures.
